(19) United States
(12) Patent Application Publication
(10) Pub. No.: US 2008/0258206 A1
(43) Pub. Date: Oct. 23, 2008

(54) Self-Aligned Gate Structure, Memory Cell Array, and Methods of Making the Same

(75) Inventor: Franz Hofmann, Munchen (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 11/736,327

(22) Filed: Apr. 17, 2007

(51) Int. Cl. H01L 27/108; H01L 21/8242

(52) U.S. Cl. 257/327; 438/129; 257/E21.622; 257/E21.623; 257/E21.628; 257/E27.097

(57) ABSTRACT

A self-aligned gate structure includes a first gate region and a second gate region. The first gate region extends in semiconductor substrate portions to a lesser depth than in isolation trenches that are adjacent to the semiconductor substrate portions. The first gate region comprises a first conductive material. The second gate region is adjacent to the first gate region and extends above a surface of the semiconductor substrate. The second gate region includes a second conductive material.

### BACKGROUND

Memory cells of a dynamic random access memory (DRAM) generally comprise a storage capacitor for storing an electrical charge which represents data to be stored, and an access transistor which is connected with the storage capacitor. A memory cell array further comprises wordlines which are coupled to the gate electrodes of corresponding transistors as well as bitlines which are coupled to corresponding doped portions of the transistors. One transistor type which may be employed is the FINFET. Another transistor type is a modification of a FINFET in which the channel surface is recessed with respect to the substrate surface. In cases in which the gate electrodes as well as the wordlines are to be formed by separate processing steps, efforts are made to properly align the wordlines with respect to the gate electrodes.

Generally, a DRAM memory cell array having a high packaging density which can be produced by a simple robust process having a low complexity and a high yield are desirable.

### SUMMARY

Described herein is a method of forming a gate structure, a method of forming a memory cell array, A self-aligned gate structure, and a memory cell array. The self-aligned gate structure comprises a first gate region and a second gate region. The first gate region extends in semiconductor substrate portions to a lesser depth than in isolation trenches that are adjacent to the semiconductor substrate portions. The first gate region comprises a first conductive material. The second gate region is adjacent to the first gate region and extends above a surface of the semiconductor substrate. The second gate region comprises a second conductive material.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

The accompanying drawings are included to provide a further understanding of exemplary embodiments and are incorporated in and constitute a part of this specification. The drawings illustrate the exemplary embodiments and together with the description serve to explain the principles. Other embodiments and many of the intended advantages will be readily appreciated, as they become better understood by reference to the following detailed description. The elements of the drawings are not necessarily to scale relative to each other. Like reference numbers designate corresponding similar parts.

The exemplary embodiments are explained in more detail below, where:

FIGS. 1 to 6 show various views of a substrate when performing the method of forming a gate structure according to an embodiment;

FIGS. 7A to 7C show various views of an exemplary memory cell;

FIGS. 8A to 8D show cross-sectional views of a substrate when performing another method according to another embodiment;

FIGS. 8E and 8F show cross-sectional views of an exemplary transistor, which may be formed according to an embodiment;

FIG. 9 shows a cross-sectional view of a substrate when performing a method according to a further embodiment;

FIGS. 10A and 10B show various views of a substrate of a memory cell according to another embodiment;

FIG. 11 shows a plan view of an exemplary memory device;

FIG. 12 shows an exemplary flow-chart illustrating a method according to an embodiment;

FIG. 13 shows another exemplary flow-chart illustrating a method according to another embodiment; and

FIG. 14 shows a schematic view of an electronic device according to an embodiment.

### DETAILED DESCRIPTION

In the following detailed description reference is made to the accompanying drawings, which form a part hereof and which illustrate exemplary embodiments. In this regard, directional terminology such as “top”, “bottom”, “front”, “back”, “leading”, “trailing” etc. is used with reference to the orientation of the figures being described. Since components of exemplary embodiments can be positioned in a number of different orientations, the directional terminology is used for purposes of illustration and is in no way limiting. Is to be understood that other embodiments may be utilized and structural or logical changes may be made without departing from the scope defined by the claims.

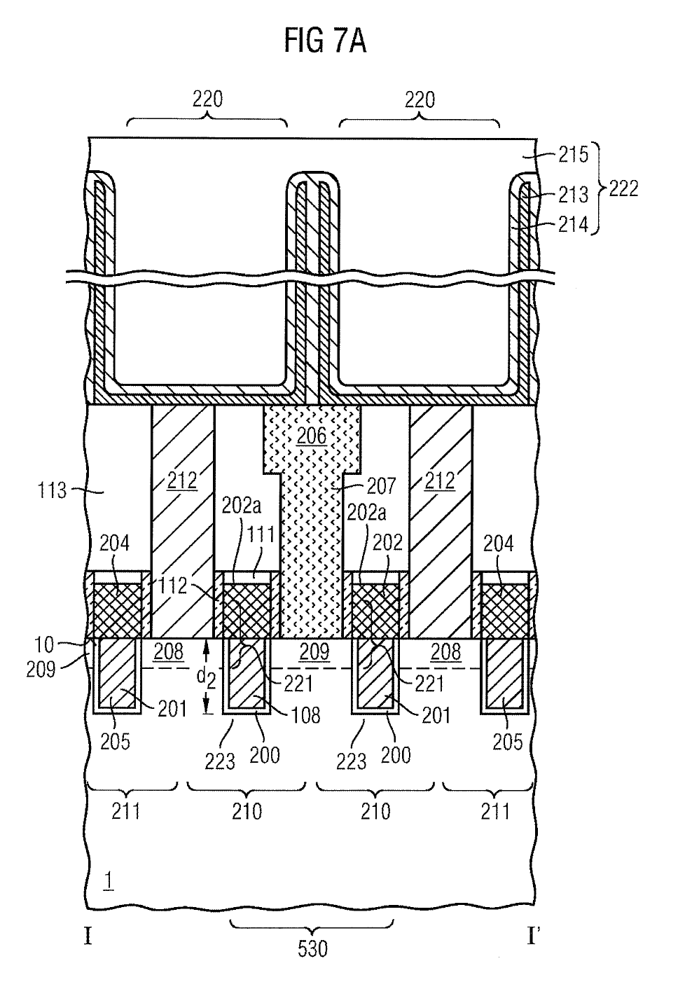

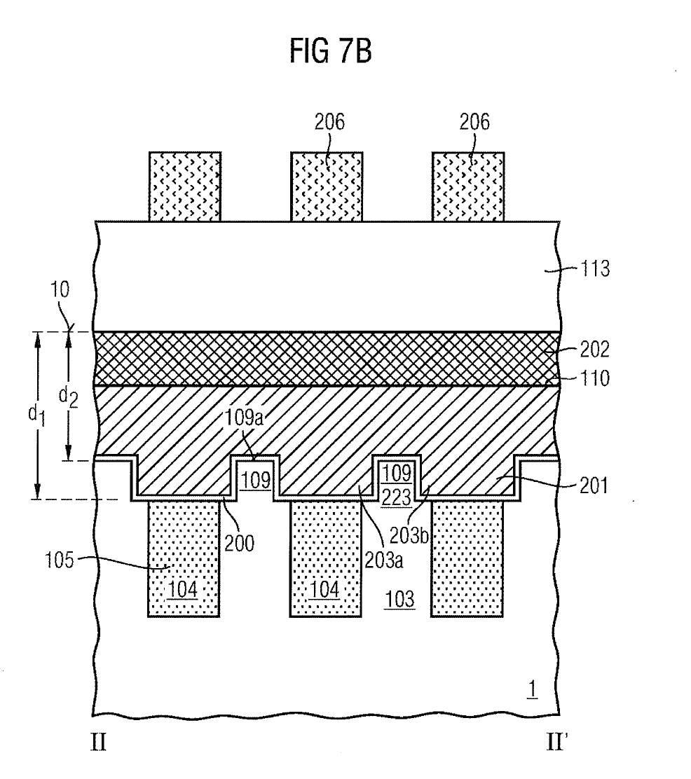

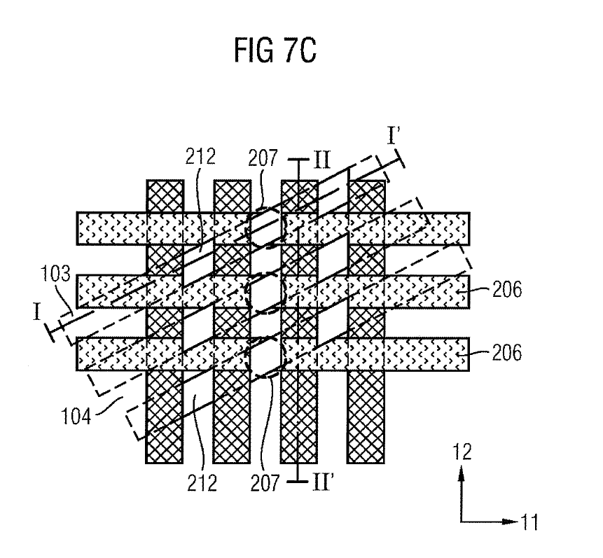

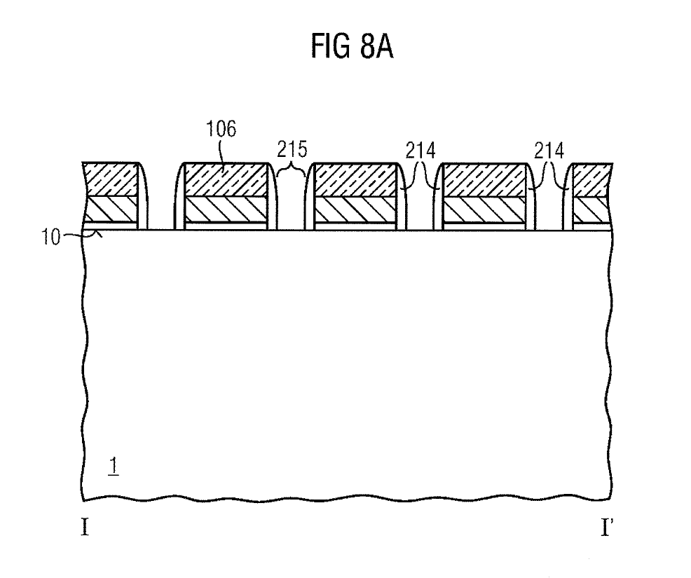

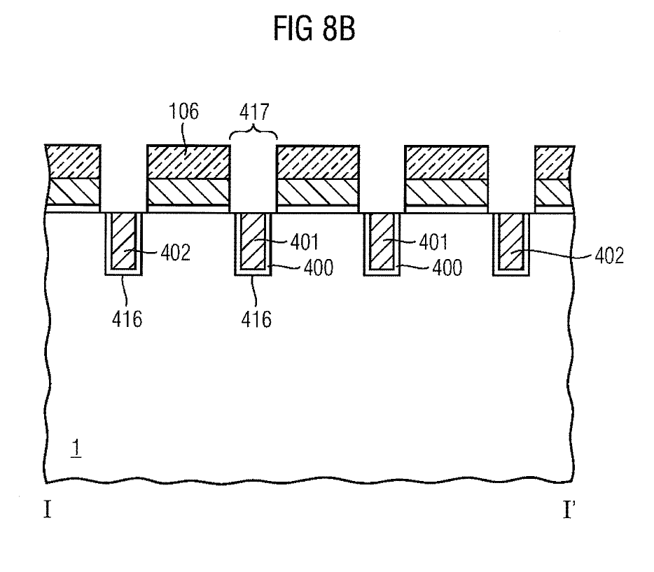

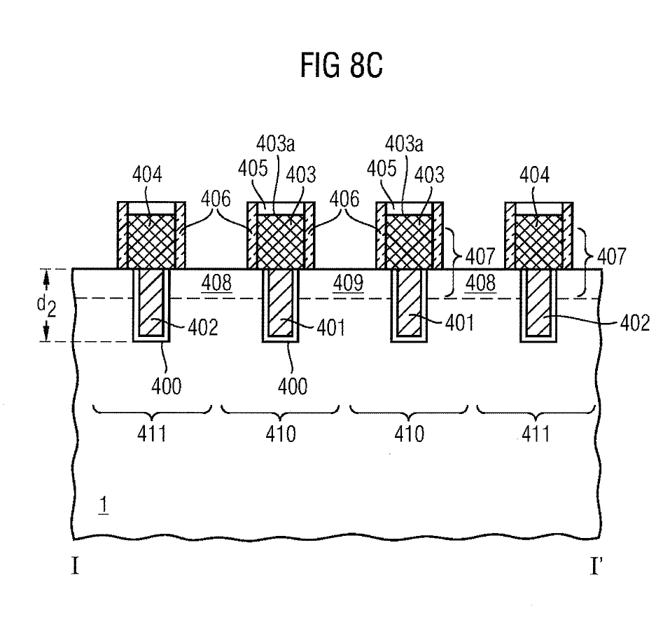

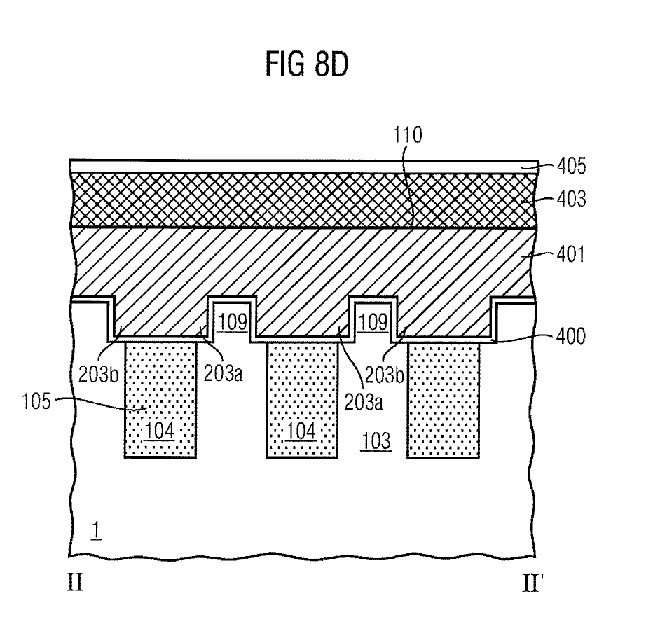

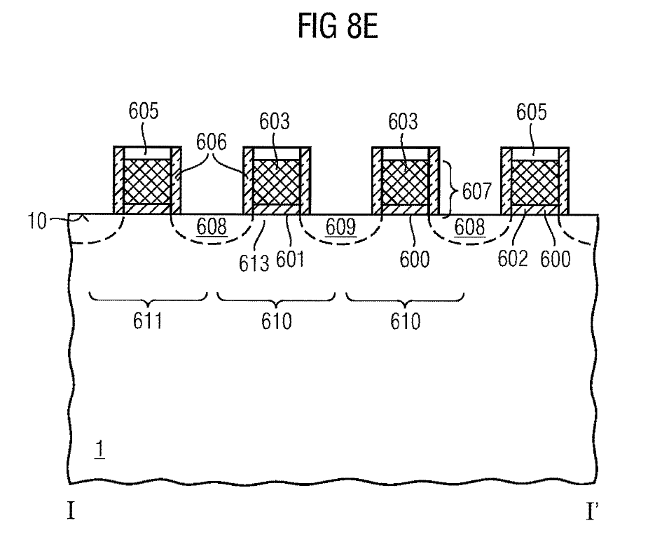

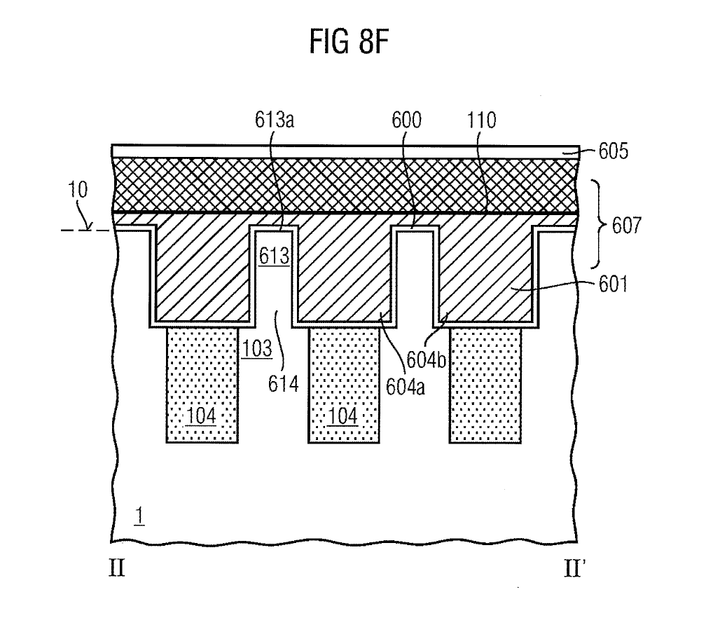

FIGS. 7A and 7B, as well as FIG. 8C and FIG. 8E illustrate, for example, self-aligned gate structures 221, 407, and 607 according to exemplary embodiments. The self-aligned gate structure comprises a first gate region 201, 401, 601 which extends in semiconductor substrate portions 103 to a lesser depth than in isolation trenches 104. As can be seen from FIGS. 7B, 8D and 8F, the isolation trenches are adjacent to the semiconductor substrate portions 103 and the first gate region 201, 401, 601 may be made of a first conductive material. The self-aligned gate structure further comprises a second gate region 202, 204, 403, 603, the second gate region extending above a surface of the semiconductor substrate 10. The second gate region may be made of a second conductive material.

By way of example, the first gate region may extend in the semiconductor substrate to a depth d2 of at least 100 nm. For example, the depth d2 is measured from the substrate surface 10 to the bottom portion of the gate groove 108 which is formed in the substrate portion 103. By way of example, the depth d2 may also be less than 100 nm. According to an embodiment, which is illustrated in FIGS. 8E and 8F, the first gate region may not substantially extend in the semiconductor substrate 1. In this case, no gate groove 108 is substantially defined in the semiconductor substrate portion 103 as will be described with reference to FIGS. 8E and 8F.

According to an embodiment, the first gate region 201 may extend in the isolation trenches 104 to a depth d1 of at least 150 nm. By way of example, the depth d1 is measured from the substrate surface to the bottom portion of the gate electrode 201. The first conductive material of the first gate region may comprise polysilicon. Moreover, according to an exemplary embodiment, the second conductive material of the second gate region may comprise a metal or a metal silicide. As is shown in FIG. 7B, for example, the first gate region may extend in the isolation trenches 104 to the depth d1 which may be substantially constant in each of the isolation trenches 104. To be more specific, the gate electrode 201 enclosing the active region 109 may be defined in such a manner that the vertical portions 203a, 203b of the gate electrode are merged. As is clearly to be understood, part of the first gate region may likewise extend above the substrate portion, as is, for example, shown in FIG. 8E.

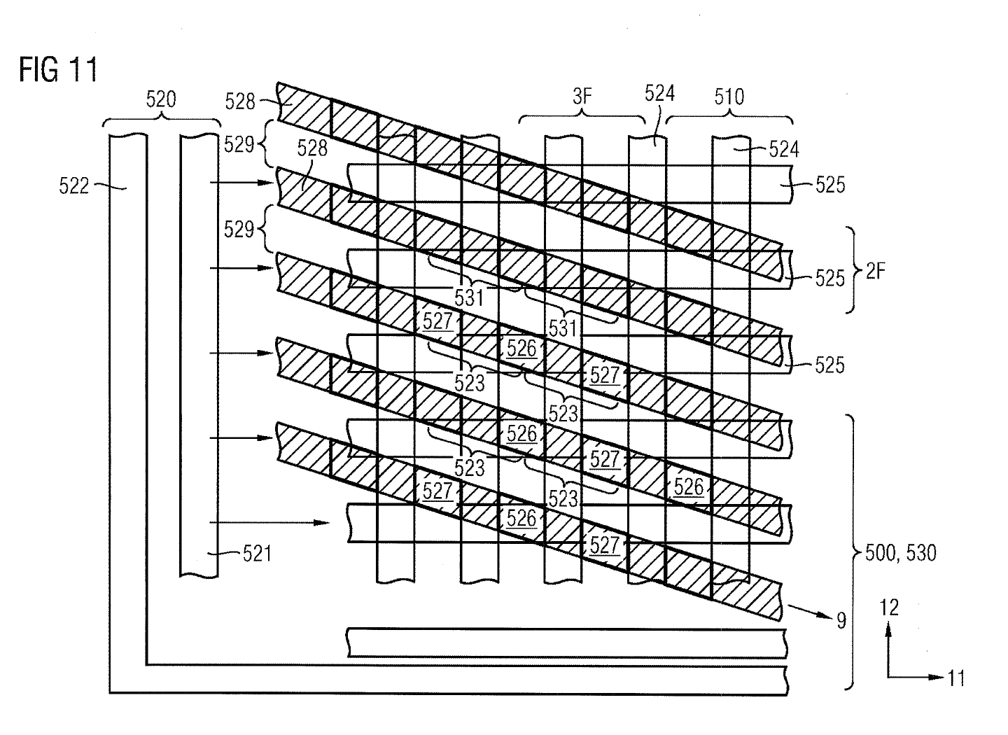

FIG. 11 shows an integrated circuit 530 or a memory device 500 comprising a memory cell array 510, wherein each of the memory cells 523 comprises a transistor 531 including a self-aligned gate structure as has been explained above. For example, as is shown in FIG. 7A, the second gate regions 202 may form part of corresponding wordlines.

In the memory cell array shown in FIG. 11, active areas 528 and isolation trenches 529 are formed in a semiconductor substrate. In this respect, the terms “wafer”, “substrate” or “semiconductor substrate” used in the present description may include any semiconductor-based structure that has a semiconductor surface. Wafer and structure are to be understood to include silicon, silicon-on-insulator (SOI), silicon-on sapphire (SOS), doped and undoped semiconductors, epitaxial layers of silicon supported by a base semiconductor foundation, and other semiconductor structures. The semiconductor need not be silicon-based. The semiconductor could as well be silicon-germanium, germanium, or gallium arsenide.

Transistors 523 are formed in the active areas 528. The transistors 523 are implemented as FINFETs and the active areas are disposed in parallel rows extending in a first direction. The memory cell array shown in FIG. 11 further comprises bitlines 525 which run along a second direction 11 which is different from the first direction 9. Each of the bitlines 525 intersects a plurality of different rows of active areas 528. The memory cell array further comprises wordlines 524 which run along a third direction 12 which is different from the first direction 9 and the second direction 11. A top surface of a conductive material of the wordlines is disposed above the semiconductor substrate. Accordingly, a cross-sectional view of a corresponding memory cell is for example, shown in FIGS. 7A and 8C. As can be seen from FIGS. 7A and 8C, the top surface 202a, 403a of the conductive material of the wordlines is disposed above the substrate surface 10. Moreover, as can be seen from the cross-sectional view shown in FIG. 7B, the transistors are implemented as FinFETs.

As will be used herein after, the term “FinFET” refers to a field effect transistor comprising a first and a second source/drain portion. A channel is disposed between the first and second source/drain portions. A gate electrode is insulated from the channel by a gate dielectric. The gate electrode is configured to control the conductivity of the channel. In a FinFET, the channel has the shape of a fin or a ridge. Moreover, the gate electrode encloses the channel at two or three sides thereof. Accordingly, if the channel is confined by isolation trenches in a longitudinal direction, part of the gate electrode may extend into the isolation trenches so as to define vertical portions. Nevertheless, part of the gate electrode may likewise extend in a substrate portion in a region which is adjacent to the isolation trenches. The gate electrode of a FinFET comprises vertical portions that are adjacent to the channel portion.

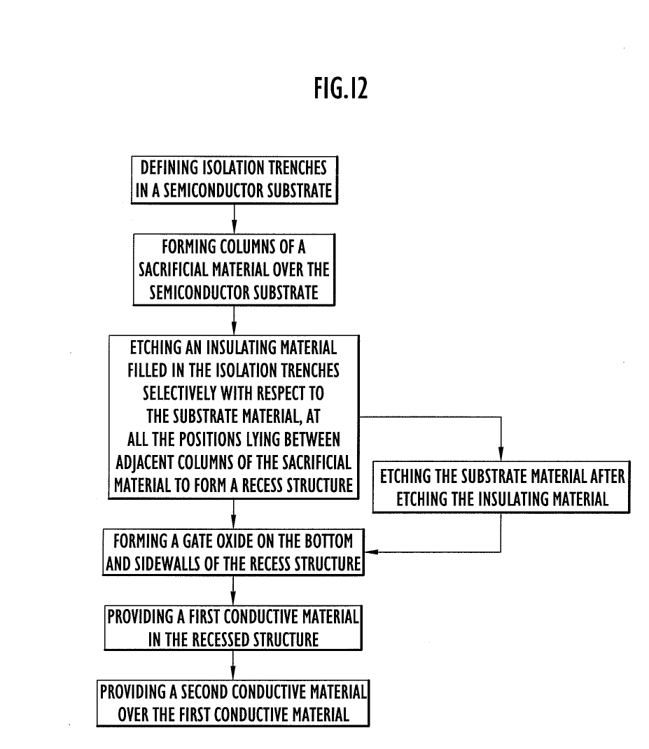

In the following, a method of forming a gate structure as well as a memory cell array as has been explained above will be explained. FIG. 12 shows an exemplary flow-chart illustrating a method according to an embodiment.

According to an embodiment, a method of forming a gate structure comprises: defining isolation trenches in a semiconductor substrate (S1), forming columns of a sacrificial material over the semiconductor substrate (S2), etching an insulating material filled in the isolation trenches selectively with respect to the substrate material, at all the positions lying between adjacent columns of the sacrificial material to form a recess structure (S3), forming a gate oxide on the bottom and sidewalls of the recess structure (S4), and providing a first conductive material in the recessed structure (S5). As is indicated by broken lines in FIG. 12, the method may further comprise etching the substrate material (S6) after etching the insulating material. Moreover, as is also indicated by broken lines in FIG. 12, the method may further comprise providing a second conductive material over the first conductive material (S7). As will be explained hereinafter, by way of example, the substrate material may be isotropically or anisotropically etched. In this respect, the term “isotropically etching” means that the substrate material is etched in a first direction (for example, vertical direction) and in a second direction (for example, horizontal direction) which is perpendicular with respect to the first direction with substantially the same etching rate. As a result, the substrate is recessed in the vertical direction at the same rate as in the horizontal direction. In contrast, the term “anisotropic etching” refers to an etching, in which, for example the substrate is etched in a vertical direction at a much higher etching rate than in a horizontal direction. For example, the material may not be etched in a horizontal direction or there may be predetermined ratio of the two etching rates in vertical and horizontal direction. Moreover, the term “selectively etching” refers to an etching process in which a first material is etched at a much higher etching rate than a second material. For example, a ratio of the etching rates may be more than 3:1, for example 5:1 or 10:1 or even more.

The first conductive material may, for example, comprise polysilicon. Moreover, the second conductive material may comprise a metal or a metal silicide. The columns may be formed as lines which cover several adjacent isolation trenches, respectively. Nevertheless, the columns may be as well formed as segments of lines which only cover one or two isolation trenches. According to an exemplary embodiment, after forming the columns, the entire surface of the isolation trenches is uncovered at positions which lie between the columns. Accordingly, no further resist material covers portions of the isolation trenches so as to cause a further pattern to be etched into the isolation trenches.

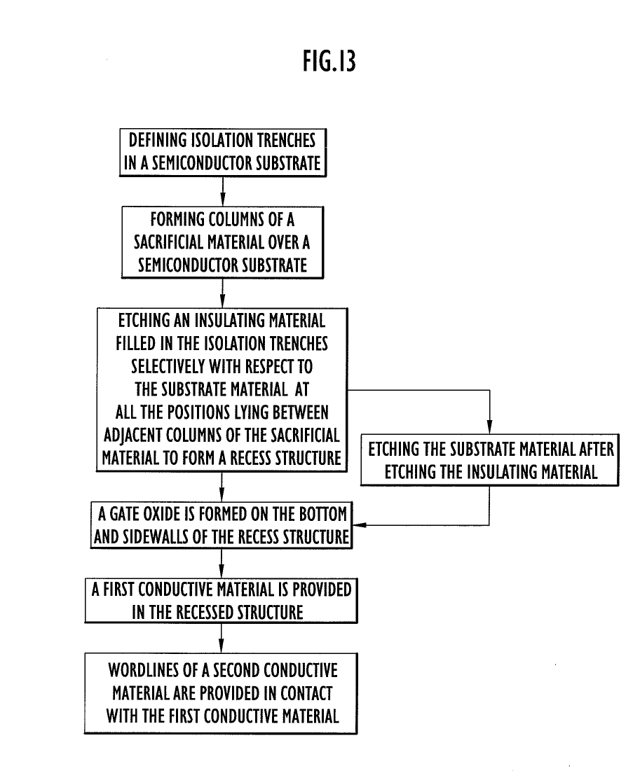

According to a further exemplary embodiment, which is illustrated in FIG. 13, a method of forming a memory cell array comprises: defining isolation trenches in a semiconductor substrate (S11) and forming columns of a sacrificial material over a semiconductor substrate (S12). Subsequently, adjacent columns of the sacrificial material are used as a guide for selectively etching an insulating material filled in the isolation trenches with respect to the substrate material at all the positions lying between adjacent columns of the sacrificial material to form a recess structure (S13). Thereafter, a gate oxide is formed on the bottom and the sidewalls of the recess structure (S14). Then, a first conductive material is provided in the recessed structure (S15) and wordlines of a second conductive material are provided in contact with the first conductive material (S16).

As is indicated by broken lines in FIG. 13, the method may further comprise etching the substrate material (S17) after etching the insulating material. By way of example, the adjacent columns of the sacrificial material may also be used as a guide for providing the wordlines. Thereby, the position of the wordlines can be aligned with respect to the position of the gate structure. According to an exemplary embodiment, the wordlines may be formed such that an upper surface thereof is disposed beneath the surface of the substrate. In other words, for example, a buried wordline is formed. Alternatively, the wordlines may also be formed such that an upper surface thereof is disposed above the surface of the substrate.

According to an exemplary embodiment, a method of forming a memory cell array comprises: defining isolation trenches in a semiconductor substrate, defining vertical portions of a gate electrode extending in the isolation trenches, and providing wordlines in contact with corresponding gate electrodes in a self-aligned manner with respect to the gate electrodes. The step of defining isolation trenches may comprise etching isolation trenches in the semiconductor substrate. Thereafter, the trenches may be filled with an appropriate insulating material by performing a deposition method such as chemical vapor deposition or plasma enhanced chemical vapor deposition or a silicon oxide forming process such as thermal oxidation. Likewise, any combination of these methods may be used. The vertical portions of the gate electrode may be defined by etching portions of the isolation trenches and, subsequently, filling the etched portions with a conductive material. The wordlines may be provided in a self-aligned manner by using columns as a guide for defining the vertical portions of the gate electrode and for defining the wordlines. As an alternative, the wordlines may be formed in a gate groove which is formed in the substrate surface. The wordlines may be provided by performing a deposition method. By way of example, the material of the wordlines may be deposited as a layer, followed by a patterning step. Alternatively, the material of the wordlines may be filled in a pattern of a sacrificial material so as to obtain a predetermined pattern.

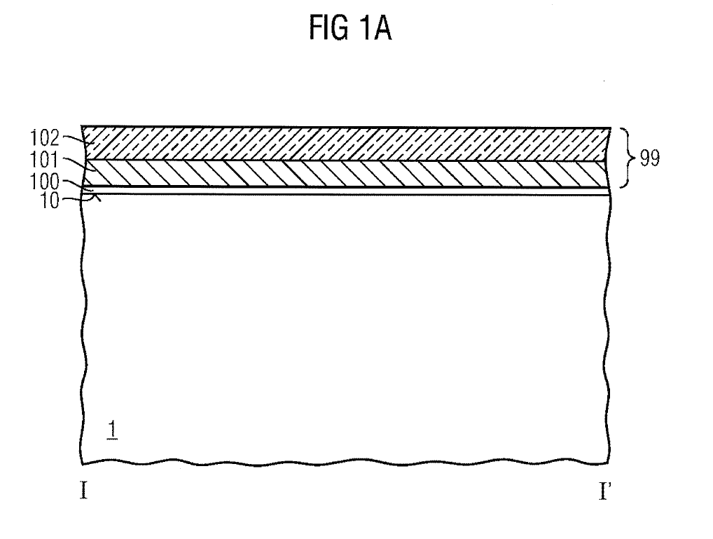

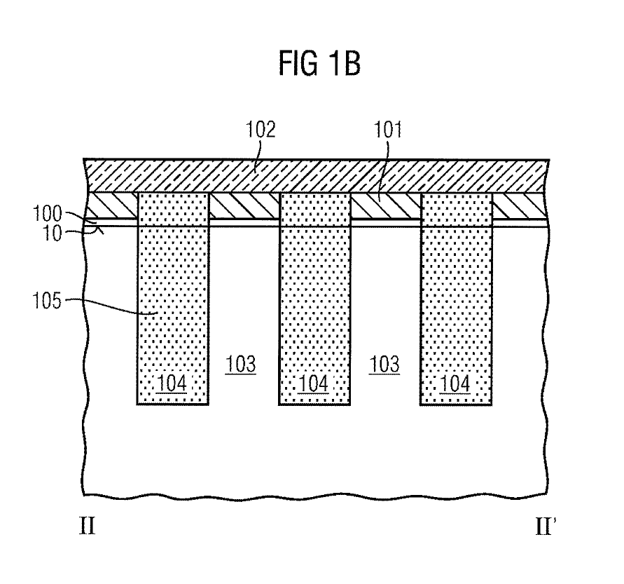

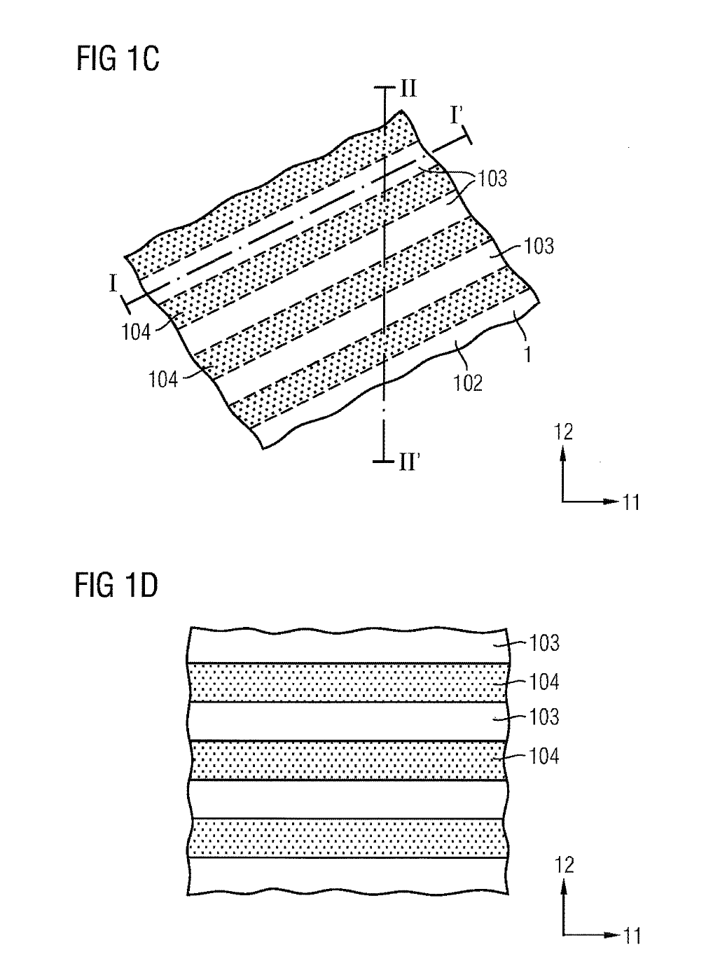

In the following, an exemplary method of forming a gate structure as well as an exemplary method of forming a memory cell array will be explained. For implementing the method of an exemplary embodiment, first a substrate 1 having a surface 10 is provided. For example, the substrate may be a semiconductor substrate of the manner as has been explained above. In the following, various cross-sectional views and plan views are shown. FIG. 1C shows a plan view in which also the directions of the cross-sectional views are shown.

On the surface 10 of the semiconductor substrate, first, a suitable hardmask layer stack may be deposited. By way of example, the hardmask layer stack 99 may comprise a silicon oxide layer 100, a polysilicon layer 101 as well as a silicon nitride layer 102. For example, the silicon oxide layer 100 as well as the polysilicon layer 101 may act as a gate dielectric and a gate electrode of a transistor which is to be formed in the peripheral portion, respectively. The silicon oxide layer 100 may have a thickness of at least 1 nm. The thickness may be less than 5 nm. Moreover, the polysilicon layer may have a thickness of approximately more than 40 nm and less than 80 nm. Moreover, the silicon nitride layer 102 may have a thickness of more than 40 nm and, for example, less than 120 nm. Thereafter, isolation trenches are defined in the semiconductor substrate. This may be accomplished by performing a generally known process. By way of example, first, a photoresist layer is applied and patterned using a mask having a lines/spaces pattern. The width of the lines and spaces of the mask may be equal to F, for example, the structural feature size of the technology employed. By way of example, F may be less than 150 nm, for example, 120 nm, 110 nm, 80 nm, 70 nm, 50 nm or even less. As is illustrated with reference to FIG. 1C, the lines for defining the isolation trenches 104 and the active areas 103 may be slanted with respect to the directions 11 and 12. For example, the directions 11 and 12 may correspond to the directions in which the wordlines and the bitlines of a corresponding memory cell array may be formed.

Moreover, as is generally known in the art, the mask for defining the isolation trenches may be implemented in a manner that rows of active areas may be formed. For example, the active areas may be implemented as segments of lines or islands. After photolithographically patterning the photoresist layer, the pattern is transferred into the hardmask layer stack 99 and the substrate material is etched, taking the patterned hardmask as an etching mask. By way of example, the isolation trenches 104 may be etched to a depth of approximately more than 150 nm. By way of example, the isolation trenches 104 may have a depth of approximately 200 nm, the depth being measured from the substrate surface. Thereafter, the isolation trenches 104 are filled with an insulating material 105, by way of example, silicon oxide (SiO₂). For example, this may be accomplished by performing a sidewall oxidation step, followed by a step of depositing silicon oxide. Thereafter, the insulating material 105 may be recessed, for example, by a back-etching step. Then, a further silicon nitride material is deposited. Optionally, a planarizing step may be performed so that finally the planar surface is obtained. A cross-sectional view of the resulting exemplary structure is shown in FIG. 1B, this view being taken in a direction which intersects the direction of the isolation trenches 104. As can be seen, isolation trenches 104 are formed in the silicon substrate material 1. Between adjacent isolation trenches 104 active areas 103 are defined. Above the active areas 103, columns of the polysilicon material 101 are disposed.

FIG. 1D shows a further example of an arrangement of active area lines 103 and isolation trenches 104. As is shown in FIG. 1D, the isolation trenches 104 as well as the active areas 103 extend in the direction 11, for example, the direction in which the bitlines are to be formed in a later processing step.

Thereafter, the silicon nitride layer 106 may be patterned using a mask having a lines/spaces pattern. By way of example, the line width of each of the lines of the mask may be approximately equal to F. For example, the silicon nitride layer 102 is patterned by using a photolithographic method as is generally well known. Accordingly, after correspondingly patterning a suitable photoresist material, the hardmask layer stack 99 comprising, for example, the silicon oxide layer 100, the polysilicon layer 101 and the silicon nitride layer 102 are etched. Thereafter, the remaining portions of the photoresist material are removed. During these processing steps, for example, the support portion may be covered by a suitable resist material so that the silicon nitride layer is not etched.

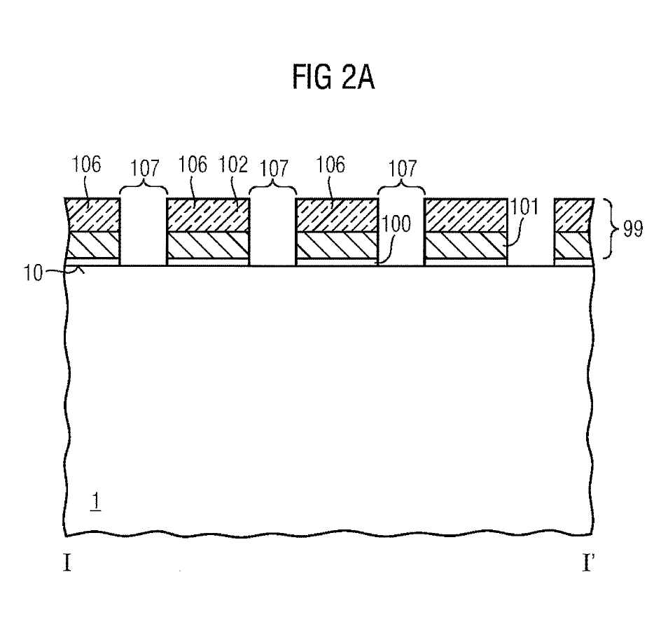

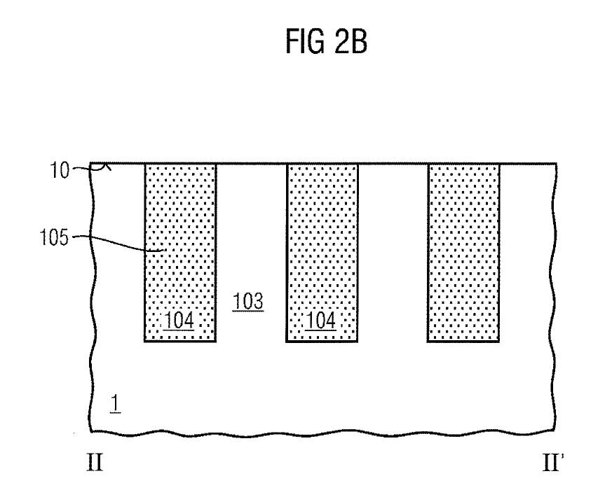

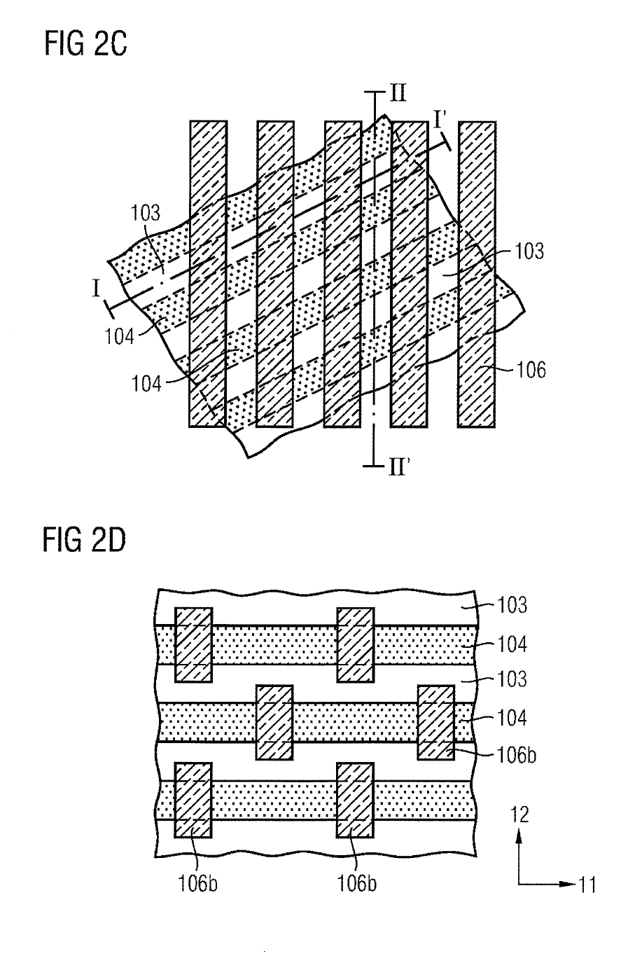

FIG. 2A shows an exemplary cross-sectional view of the array portion resulting from the above described etching steps. As can be seen, lines 106 of the hardmask layer stack 99 are provided. Moreover, in the spaces 107 between adjacent lines 106, a surface 10 of the substrate 1 is uncovered. Moreover, FIG. 2B shows a cross-sectional view in a space 107 between adjacent lines 106 between II and II′ as can be seen from FIG. 2C. As is shown, the entire surface 10 of the substrate 1 as well as of the isolation trenches 104 now is uncovered.

FIG. 2C shows an exemplary plan view of the substrate. As can be seen, the lines 106 are slanted with respect to the isolation trenches 104 so that one line 106 intersects a plurality of isolation trenches 104 and a plurality of different active areas 103.

FIG. 2D shows an exemplary plan view of a substrate in a case in which the active areas 103 and the isolation trenches 104 run in the section direction 11. By way of example, the lines 106 may be formed as segments of lines 106b so that another layout may be implemented. Nevertheless, as is clearly to be understood, the hardmask layer stack 99 may also be patterned so as to form continuous lines in the manner as has been shown in FIG. 2C, for example.

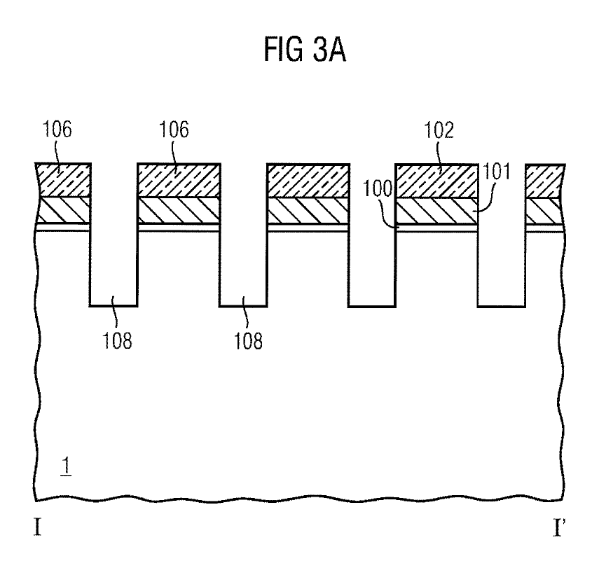

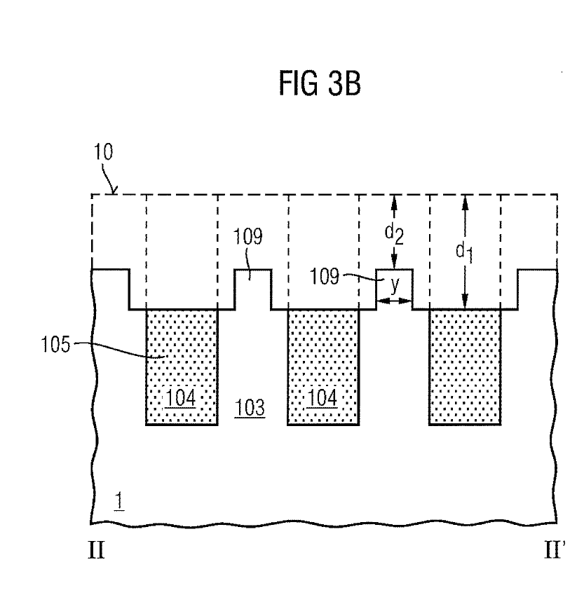

Thereafter, an etching step of etching silicon oxide may be performed. For example, this may be a selective etching step which only etches silicon oxide. By way of further example, this may be accomplished by a reactive ion etching step as is commonly known. For example, this etching step may etch approximately more than 150 nm, by way of example, about 200 nm of the silicon oxide material 105. Accordingly, by this etching step a depth d1 of the surface of the insulating material 105 in comparison to the original substrate surface 10 is achieved. Since, as has been shown with reference to FIG. 2B, the surface of the isolation trenches 105 now is completely uncovered, the insulating material 105 is etched in the isolation trenches 104 to a constant depth d1 as is indicated by dotted lines in FIG. 3B. Thereafter, optionally, silicon material may be etched. By way of example, by this etching step approximately more than 50 nm, for example more than 100 nm, for example about 150 nm may be etched. This etching may be selective with respect to silicon oxide or not. Moreover, this etching step may be isotropic or anisotropic. By way of example, this etching may be anisotropic so that a predetermined amount of silicon material is horizontally etched whereas a different amount is vertically etched. By way of example, the etching rates may be adjusted so that the surface of the active area 103 is recessed by an amount d2 with respect to the substrate surface 10. At the same time, the fin region 109 may be narrowed by an amount x so as to obtain a desired fin width y. An exemplary cross-sectional view of the resulting structure is shown in FIG. 3A. As can be seen from FIG. 3A, now gate grooves 108 are formed in the substrate surface 10. Moreover, as can be seen from FIG. 3B, a narrowed fin region 109 is formed. As has been explained above, by adjusting the etching parameters, a predetermined fin width y may be adjusted. Moreover, the material of the isolation trenches 104 may be recessed by a predetermined amount. FIG. 3C shows an exemplary plan view of the resulting structure.

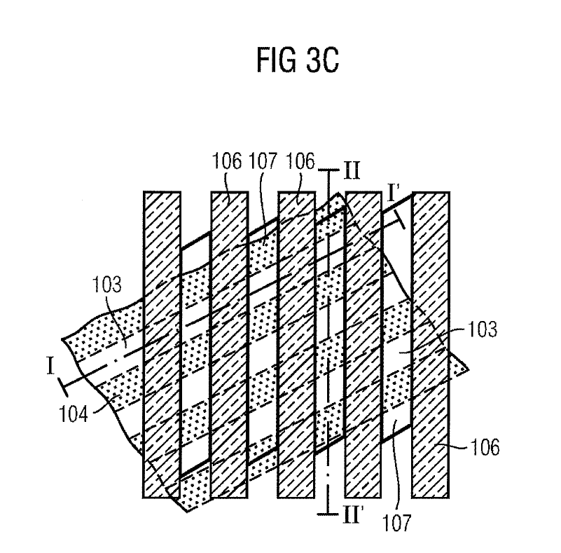

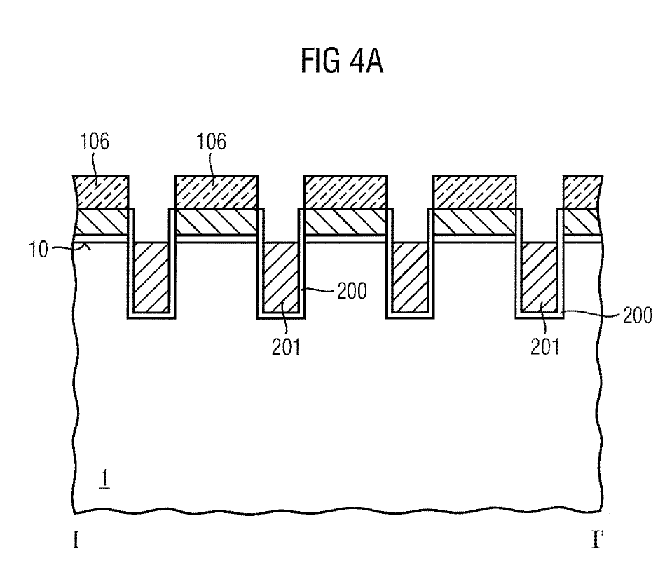

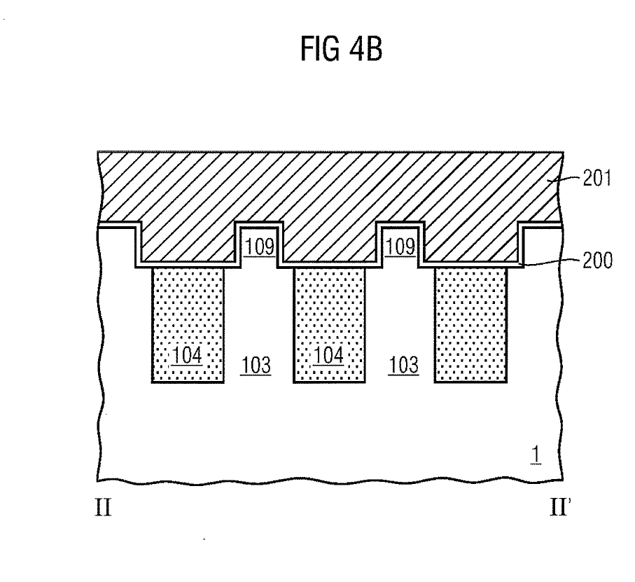

Thereafter, a gate dielectric 200 may be formed in a manner as is conventional. Thereafter, polysilicon material may be deposited and recessed. For example, the polysilicon material may be recessed so that the upper surface thereof is at the same level as the substrate 10 or above. As a result, a gate electrode 201 is formed. The top surface of the gate electrode 201 may be at the same height as the substrate surface 10, for example. The gate electrode 201 is insulated from the substrate material by the gate dielectric 200 as is shown in FIG. 4A. FIG. 4B shows a cross-sectional-view of the substrate between two adjacent silicon nitride lines 106. As can be seen from FIG. 4B, the entire width between adjacent silicon nitride lines 106 now is filled with the gate dielectric 200, followed by the polysilicon material.

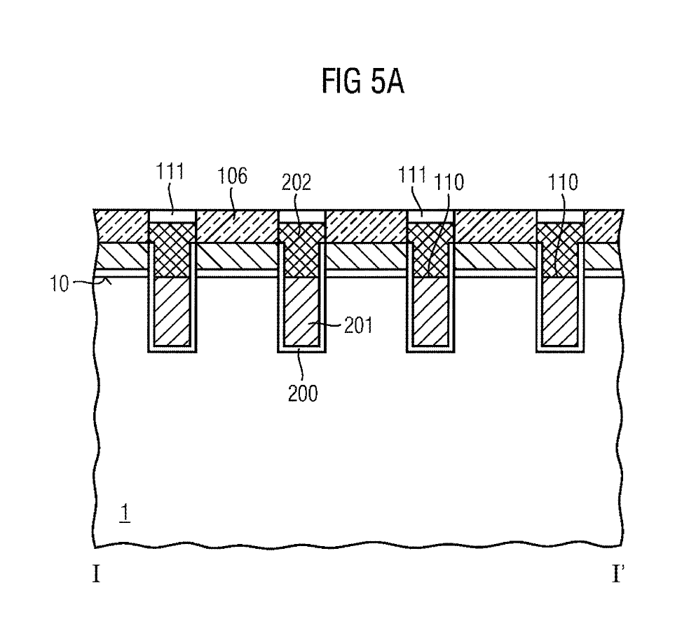

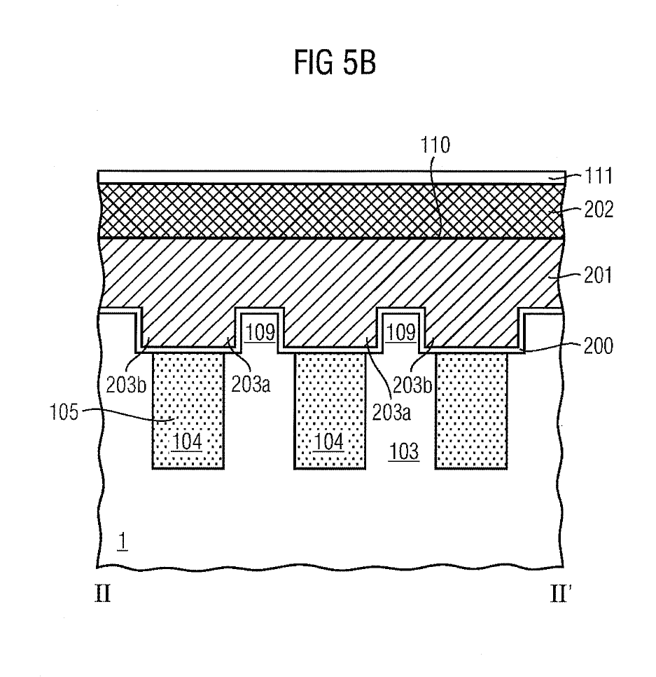

Thereafter, the material of the wordlines 202 may be provided. By way of example, this may be accomplished by providing a barrier material such as titanium nitride. By way of example, such a barrier layer 110 may have a thickness of more than 8 nm, for example, about 10 nm. Thereafter, a wordline material may be deposited. By way of example, this may be accomplished by depositing a metal layer or a metal compound layer, for example a metal silicide layer. A thickness of the metal or metal compound layer is selected so that the spaces 107 are completely filled. Thereafter, a CMP (chemical mechanical polishing) step is performed so as to obtain a planar surface. Then, the metal is recessed, followed by a step of providing an insulating layer 111, for example, made of silicon oxide. Then, a further CMP step is performed. FIGS. 5A and 5B show exemplary cross-sectional views of the resulting structure. As can be seen, between adjacent lines 106 now wordlines 202 are formed. The wordlines 202 are disposed above the gate electrodes 201. Since as has been explained above, adjacent columns of the sacrificial material 106 have been used as a guide when providing the wordlines, a perfect alignment between the wordlines 202 and the gate electrode 201 may be obtained. The width of the wordlines 202 may be equal to the width of the gate electrode 201. In a space 107 between adjacent silicon nitride lines 106, the barrier layer 110 as well as the wordline 202 covered by silicon oxide layer 111 are provided. Thereafter, the lines 106 may be removed. By way of example, this may be accomplished by performed suitable etching steps for removing the silicon nitride layer, the polysilicon layer as well as the silicon oxide layer. Then, a sidewall spacer 112 of a suitable material such as silicon nitride may be provided as is common so as to be adjacent to the wordlines 202. By way of example, the silicon nitride spacer 112 may have a thickness of approximately more than 5 nm (e.g., approximately 10 nm).

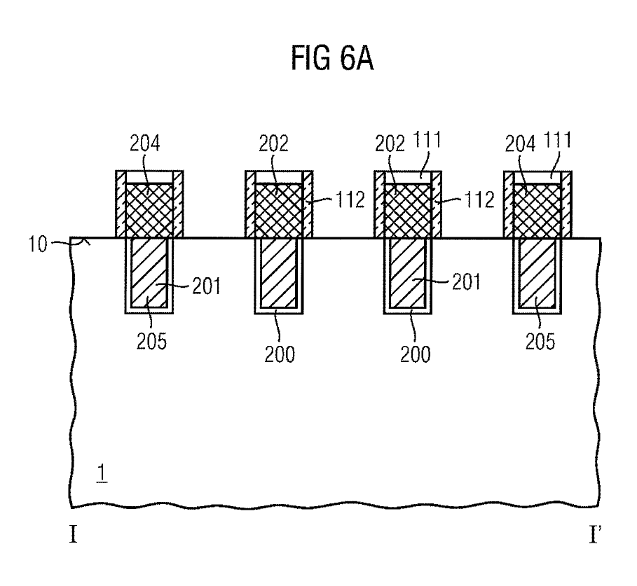

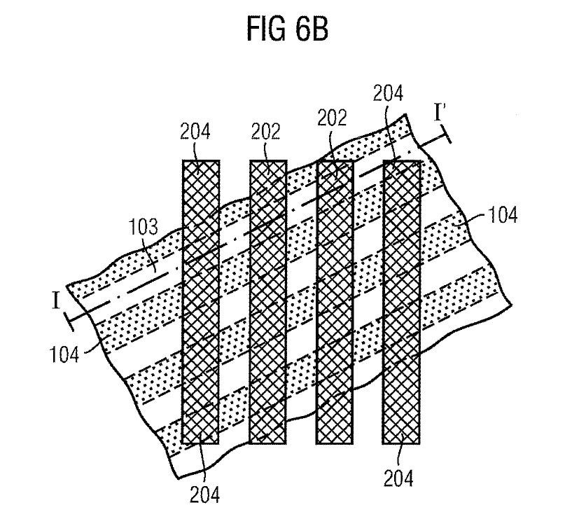

FIG. 6A shows an exemplary cross-sectional view of the resulting structure. Moreover, FIG. 6B shows an exemplary plan view of the resulting structure. As can be seen, now, wordlines 202 are disposed at the positions which lie in the spaces 107 between adjacent lines 106 which were present in the drawings hereinbefore. According to a specific embodiment, some of the wordlines may be implemented as so-called isolation wordlines 204. The isolation wordlines 204 are connected with isolation gates 205. These isolation gates 205 act as a corresponding gate electrode of an isolation field effect transistor which is to be formed at the corresponding positions. Such an isolation field effect transistor isolates neighboring transistors which are assigned to different memory cells.

Thereafter, the memory cell may be further processed in order to provide a corresponding memory cell. By way of example, the transistors which are to be formed in the support portion may be further processed. For example, the material for forming the gate electrodes may be correspondingly patterned. Moreover, substrate portions may be doped in order to define source/drain portions 208, 209. Thereafter, a suitable dielectric material such as silicon oxide 113 may be provided so as to completely cover the substrate surface. Then, bitline contacts 207 may be defined by correspondingly defining openings which are in contact with the second source/drain portion 209. Moreover, bitlines may be defined as is common. In addition, capacitor contacts 212 are defined in a manner as may be conventional. By way of example, bitlines 206 may be formed by a so-called damascene process in which the corresponding pattern is defined in the silicon oxide layer 113, followed by a step of depositing the material for constituting the bitlines 206. Alternatively, the insulating layer 113 may be deposited, followed by a step of depositing a layer for forming the bitlines 206 and corresponding patterning the bitlines 206. Thereafter, a further silicon oxide layer may be deposited. Then, a storage capacitor 222 may be formed in a manner as is generally well known.

FIG. 7 shows various views of an exemplary integrated circuit 530 or an exemplary memory cell. As is shown in FIG. 7A in a cross-sectional view between I and I, a memory cell 220 comprises a capacitor 222 and a transistor 210. The capacitor 222 may comprise a storage electrode 213, a capacitor dielectric 214 and a counter electrode 215. The storage capacitor 222 may be formed above the substrate surface 10. The storage electrode 213 may be connected with the first source/drain portion 208 of a corresponding transistor 210 via a capacitor contact 212. The transistor 210 comprises a first source/drain portion 208 and a second source/drain portion 209. A channel 223 is formed between the first source/drain portion 208 and the second source/drain portion 209. The conductivity of the channel 223 may be controlled by a gate electrode 201. The gate structure has been explained in detail above. The second source/drain portion 209 is connected via a bitline contact 207 to a corresponding bitline 206.

On the right hand portion of the cross-sectional view shown in FIG. 7A and on the left hand portion of this cross-sectional view isolation field effect transistors 211 are shown. These isolation field effect transistors insulate the central transistors 210 from transistors lying on the right hand side or the left hand side thereof. Each of the gate electrodes 201 is connected with a corresponding wordline 202. By addressing a corresponding wordline 202, a transistor 210 is brought into a conductive state to that a charge stored in the storage capacitor may be read via the capacitor contact 212, the first source/drain portion 208, the channel 223, the second source/drain 209, and the bitline contact 207 to a corresponding bitline 206.

FIG. 7B shows a cross-sectional view between II and II′. As can be seen, each of the transistors 210 is formed as a FINFET in which the channel 223 is enclosed at three sides by the gate electrode 201. By way of example, the vertical portions 203a, 203b are adjacent to the lateral sides of the channel 223. Moreover, a portion of the gate electrode 201 is disposed above the channel 223. As can further be seen from FIG. 7B, the channel portion 223 is narrowed with respect to the width of the first and second doped portions 208, 209 which lie before and behind the plane of the drawing shown in FIG. 7B. FIG. 7C shows an exemplary plan view of the resulting structure. As can be seen, the capacitor contacts 212, and, hence the capacitors are disposed in a pattern of a regular grid. Accordingly, the capacitor contacts 212 as well as the bitline contacts 207 are disposed in parallel rows intersecting the active areas 103.

According to another embodiment, spacers 214 may be formed adjacent to the lines 106 before etching the gate grooves. This is illustrated with respect to FIGS. 8A to 8C. By using these spacers 214, the width of the spaces 215 between the spacers 214 is reduced with respect to the space between the columns 106. As a result, the width of the gate groove 416 may be smaller than the width of the corresponding wordlines which are to be formed. By way of example, the thickness of the spacers 214 may be adjusted so as to obtain a desired reduction in width of the gate grooves 416.

As is shown in FIG. 8A, first, spacers 214 made of a sacrificial material are formed by a commonly known method. By way of example, the spacers 214 may be made of polysilicon or any other material such as silicon nitride, silicon oxide and others. By way of example, the spacers 214 may be deposited by a conformal deposition method, followed by an anisotropic etching step so as to remove the horizontal portions of the sacrificial layer. As a result, the spacers 214 remain, the spacers being adjacent to the sidewalls of the lines 106. A cross-sectional view of an exemplary substrate is shown in FIG. 8A. As can be seen, spacers 214 are formed adjacent to the lines 106. Moreover, in the spaces 215 between adjacent spacers 214, portions of the substrate surface are uncovered. Then an etching step which may be similar to the one which has been described with reference to FIG. 3 may be performed. As a result, gate grooves 416 are formed in the silicon substrate. Due to this etching step, for example, the spacers 214 may be removed or partially removed. As can be seen, due to the presence of the spacers 214, the width of the gate grooves 416 is reduced with respect to the distance between adjacent lines 106, by way of example, the width of the spaces 417. Thereafter, a gate dielectric 400 and a gate electrode 401 may be provided in a manner which is similar to the manner as has been described with reference to FIG. 4. Moreover, since the presence of the spacers 214 mainly effects the cross-sectional view between I and I′, for the sake of simplification, the cross-sectional views between II and II′ are omitted since they are similar to the ones shown herein before.

Thereafter, a conductive material may be formed so as to fill the spaces 417, followed by a recessing step and a step of depositing an insulating material. By way of example, these steps may be similar to the steps which have been described with reference to FIG. 5. After filling the spaces 417 with the wordline material, the lines 106 may be removed. As a result, the wordlines 403, 404 will remain on the substrate surface. Thereafter, in a similar manner as has been described above with reference to FIG. 6, sidewall spacers 406 may be formed. An exemplary cross-sectional view of the resulting structure is shown in FIG. 8C. As can be seen, in FIG. 8C, a gate structure is formed comprising a first gate region which extends in the semiconductor substrate. Moreover, the gate structure comprises a second gate region which is disposed above the semiconductor substrate. The second gate region 403, 404 has a width which is larger than the width of the first gate region 401. By way of example, the structure shown in FIG. 8C may be further processed so as to obtain a corresponding transistor 410 and, optionally, isolation field effect transistors. By way of example, first and second source/drain portions 408, 409 may be defined by performing an ion implantation step. An exemplary cross-sectional view between II and II′ is shown in FIG. 8D. Since the cross-sectional view shown in FIG. 8D is very similar to the views shown in FIG. 5B, a detailed description thereof is omitted.

FIGS. 8E and 8F show cross-sectional views of an exemplary transistor which may be obtained in a case in which the substrate material is not etched after etching the insulating material. In this case the transistor corresponds to a conventional FinFET, in which the surface of the channel 613 is at the same height as the substrate surface 10. By way of example, after etching the insulating material filled in the isolation trenches, a gate oxide may be formed on the bottom and the sidewalls of the recessed structures and a first conductive material may be provided in the recessed structure. Accordingly, the vertical portions 604a, 604b of the gate electrode are formed. Moreover, the first conductive material may be recessed so as to be disposed slightly above the substrate surface 10. Thereafter, a second conductive material may be provided over the first conductive material so as to form the wordlines 603. As can be seen from FIG. 8E, the transistors 610 comprise a first source/drain portion 608 as well as a second source/drain portion 609. A channel 613 is disposed between the first and second source/drain portions 608, 609. The conductivity of the channel 613 is controlled by the gate electrode 601. Moreover, the gate electrode 601 is connected to the wordlines 603. As is shown in FIG. 8E, in the central portion two adjacent transistors 610 are formed. Moreover, isolation field effect transistors 611 are formed so as to isolate the central transistors from the transistors lying on the right-hand portion and the left-hand portion thereof. The isolation field effect transistor may comprise a corresponding isolation gate electrode which is connected with an isolation wordline. As can be seen from the cross-sectional view shown in FIG. 8F, the top surface 613a of the channel coincides with the substrate surface 10. To be more specific, the top surface of the channel 613a may substantially coincide with the substrate surface 10. For example, the top surface may be disposed slightly above or slightly below the substrate surface 10. The small difference between the top surface of the channel 613a and the substrate surface 10 results from the formation of the gate dielectric 600 which may be formed in such a manner, that part of the substrate material is consumed. By way of example, a barrier layer 612 may be disposed between the gate electrode 601 and the corresponding wordline 603. The materials of the gate electrode 601 and of the wordline may be the same as in the embodiments described above. Moreover, a cap layer 605 of an insulating material may be disposed on top of the wordline 603.

Accordingly, the self-aligned gate structure 607 comprises a first gate region 601 which comprises the vertical portion 604a, 604b. The first gate region extends in the semiconductor substrate portions to substantially no depth. The first gate region extends in the isolation trenches that are adjacent to the semiconductor substrate portions to a predetermined depth. Moreover, the gate structure comprises a second gate region which is adjacent to the first gate region and which extends above the surface of the semiconductor substrate. As can be seen from FIG. 8F, between adjacent vertical portions of the gate electrode, a narrowed fin portion 614 is formed. Moreover, the vertical portions 604a, 604b which are formed in contact with one single isolation trench 104 are merged so that the gate electrode 601 extends to the same depth over the whole width of the isolation trench 104.

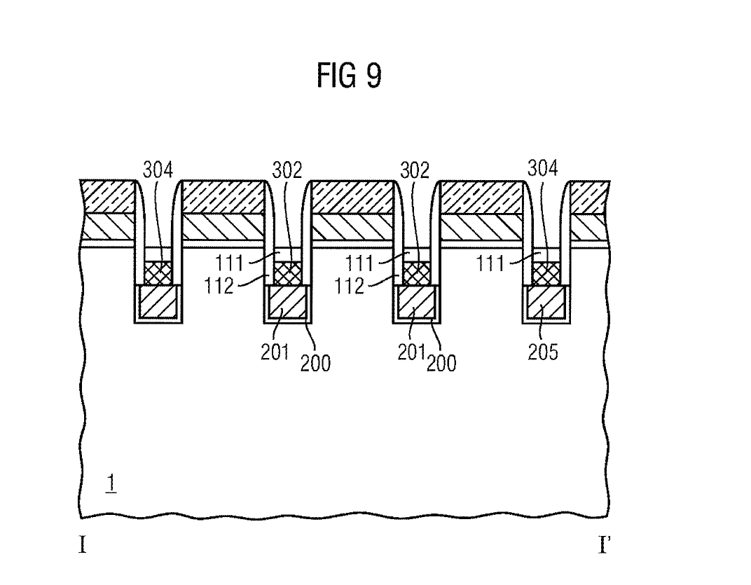

According to still another embodiment of the method described herein, the first conductive material may be further recessed to form a buried wordline. For example, as has been explained above with reference to FIG. 4, a first conductive material is provided in the gate grooves so as to form the gate electrode 201. By way of example, this conductive material may be recessed so that also wordlines may be formed in the gate grooves. This is, for example, illustrated with reference to FIG. 9. To be more specific, after filling the first conductive material, by way of example, polysilicon into the gate grooves 108, the first conductive material may be recessed so that the resulting surface lies about more than 100 nm, by way of example, 200 nm below the substrate surface. Thereafter, by way of example, sidewall spacers 112 which may be, for example, be made of a suitable dielectric material such as silicon oxide or silicon nitride may be formed so as to cover the sidewalls of the remaining portion of the gate grooves 108. Then, the second conductive material may be deposited. The second conductive material may comprise the same materials as have been described above with reference to FIG. 4. Thereafter, the second conductive material may be recessed, and a suitable dielectric material 111 may be provided so as to cover the second conductive material. As a result, as is, for example shown in FIG. 9, wordlines 302 as well as isolation wordlines 304 may be formed. Thereafter, the remaining portion of the lines 106 as well as of the spacers 112 may be removed in a manner as is conventional. Accordingly, the wordlines 302 as well as the insulating wordlines 304 are formed as completely buried wordlines.

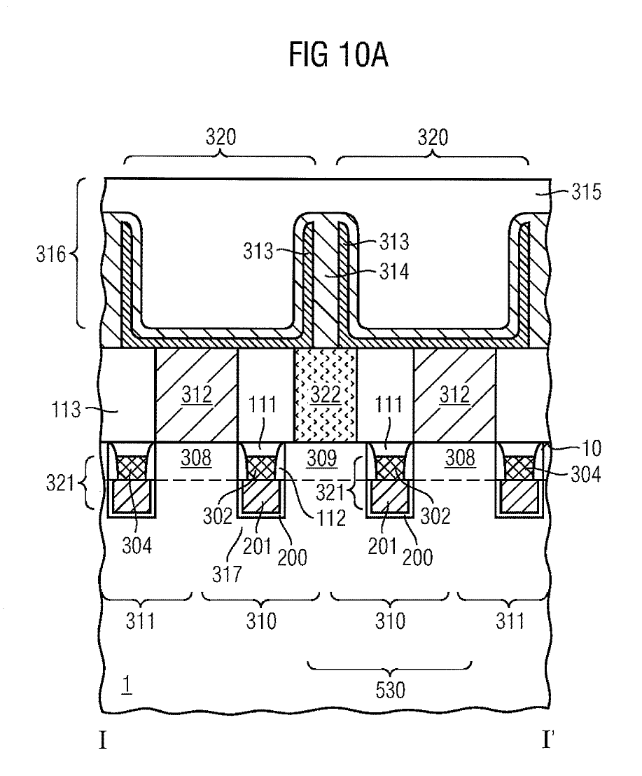

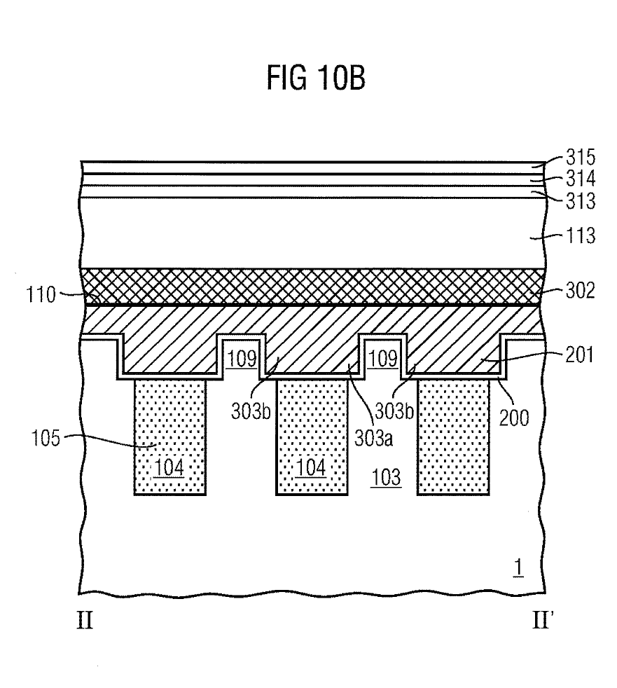

By way of example, the surface of the second conductive material may be disposed below the substrate surface 10. Thereafter, the substrate may be further processed so as to provide the first and second doped regions forming the source/drain portions 308, 309, capacitor contacts 312, bitlines 322 as well as the storage capacitors 313, 314, 315 so as to define corresponding memory cells. As a result, for example, the structure shown in FIG. 10A may be obtained. The integrated circuit 530 shown in FIG. 10A comprises various memory cells 320. Each of the memory cells 320 comprises a storage capacitor 316 as well as a transistor 310. A storage capacitor 316 may, for example, comprise a storage electrode 313, a capacitor dielectric 314 as well as a counter electrode 315. The storage electrode 313 may be connected via a capacitor contact 312 to the first source/drain portion 308 of the corresponding transistor 310. The corresponding transistor 310 comprises the first source/drain portion 308, a second source/drain portion 309 as well as a channel 317. The conductivity of the channel 317 is controlled by the gate electrode 201. The gate electrode 201 is insulated from the channel by gate dielectric 200. The top surface of the gate electrode 201 is disposed below the substrate surface 10. A wordline 302 is disposed so as to be in contact with the gate electrode 201. A top surface of the wordline 302 may be disposed beneath the substrate surface 10. The second source/drain portion 309 is in contact with a bitline 322. Accordingly, when a corresponding memory cell 320 is addressed by activating a corresponding wordline 302, data stored in the storage capacitor 316 is read via the capacitor contact 312, the first source/drain portion 308, the channel 317 and the second source/drain portion 309 to the bitline 322. Isolation field effect transistors 311 are provided so as to insulate neighboring transistors from each other. Moreover, FIG. 10B shows a cross-sectional view of the structure shown in FIG. 10A, for example, between II and II′. As can be seen, the material in the isolation trenches 104 now is recessed to a constant depth so that the vertical portions of each of the gate electrodes 303a, 303b are merged.

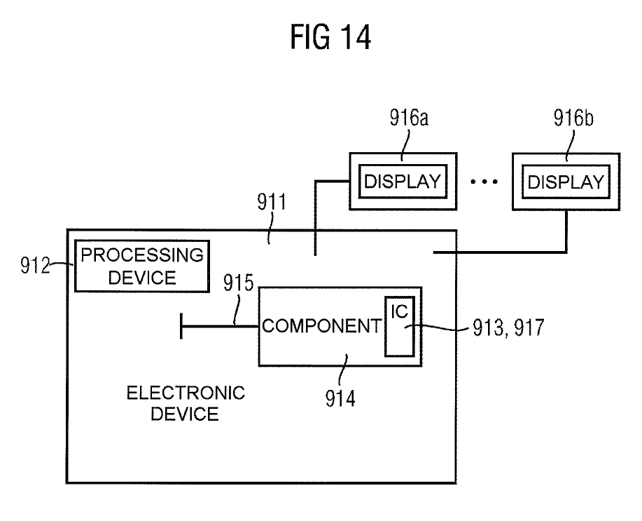

FIG. 14 schematically shows an electronic device 911 according to an embodiment. As is shown in FIG. 14, the electronic device 911 may comprise an interface 915 and a component 914 which is adapted to be interfaced by the interface 915. The electronic device 911, for example and the component 914 may include an integrated circuit 913 or a memory device 917 comprising a self-aligned gate structure as has been explained above. The component 914 may be connected in an arbitrary manner with the interface 915. For example, the component 914 may be externally placed so as to be connected with the interface 915. Moreover, the component 914 may be housed inside the electronic device 911 and may be connected with the interface 915. By way of example, it is also possible that the component 914 is removably placed into a slot which is connected with the interface 915. When the component 914 is inserted into the slot, the integrated circuit 913 is interfaced by the interface 915. The electronic device 911 may further comprise a processing device 912 for processing data. In addition, the electronic device 911 may further comprise one or more display devices 916a, 916b for displaying data. The electronic device may further comprise components which are configured to implement a specific electronic system. Examples of the electronic system comprise a computer, for example, a personal computer, or a notebook, a server, a router, a game console, for example, a video game console, as a further example, a portable video game console, a graphics card, a personal digital assistant, a digital camera, a cell phone, an audio system such as any kind of music player or a video system. For example, the electronic device 911 may be a portable electronic device.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A method of forming a gate structure, the method comprising:
defining isolation trenches in a semiconductor substrate;
forming columns of a sacrificial material over the semiconductor substrate;
filling the isolation trenches with an insulating material and selectively etching the insulating material with respect to the substrate material at positions lying between adjacent columns of the sacrificial material, thereby forming a recessed structure;
forming a gate oxide on a bottom side and sidewalls of the recessed structure; and
providing a first conductive material in the recessed structure.

2. The method of claim 1, further comprising:
etching the substrate material after etching the insulating material.

3. The method of claim 2, wherein the substrate material is isotropically etched.

4. The method of claim 1, further comprising:
providing a second conductive material over the first conductive material.

5. The method of claim 4, wherein the second conductive material comprises a metal or a metal silicide.

6. The method of claim 1, wherein the first conductive material comprises polysilicon.

7. The method of claim 1, wherein the columns are formed as lines disposed above several adjacent isolation trenches.

8. The method of claim 1, wherein the columns are formed as segments of lines.

9. The method of claim 1, wherein the columns of sacrificial material are formed such that the entire surface of the isolation trenches at positions lying between the columns is uncovered.

10. A method of forming a memory cell array, the method comprising:
forming a plurality of gate structures according to claim 1, wherein adjacent columns of the sacrificial material are used as a guide for selectively etching the insulating material; and
providing wordlines of a second conductive material in contact with the first conductive material.

11. The method of claim 10, wherein the adjacent columns of the sacrificial material are used as a guide for providing the wordlines.

12. The method of claim 10, wherein the wordlines are formed such that an upper surface thereof is disposed beneath a surface of the substrate.

13. The method of claim 10, wherein the wordlines are formed so that an upper surface thereof is disposed above a surface of the substrate.

14. A self-aligned gate structure, comprising:
a first gate region extending in semiconductor substrate portions to a lesser depth than in isolation trenches that are adjacent the semiconductor substrate portions, the first gate region comprising a first conductive material; and
a second gate region disposed adjacent the first gate region, the second gate region extending above a surface of the semiconductor substrate, the second gate region comprising a second conductive material.

15. The self-aligned gate structure of claim 14, wherein the first gate region does not substantially extend into the semiconductor substrate.

16. The self-aligned gate structure of claim 14, wherein the first gate region extends into the semiconductor substrate to a depth of at least 100 nm.

17. The self-aligned gate structure of claim 14, wherein the first gate region extends into the isolation trenches to a depth of at least 150 nm.

18. The self-aligned gate structure of claim 14, wherein the first conductive material comprises polysilicon.

19. The self-aligned gate structure of claim 14, wherein the second conductive material comprises a metal or a metal silicide.

20. The self-aligned gate structure of claim 14, wherein the first gate region extends into the isolation trenches to a first depth, the first depth being substantially constant in each of the isolation trenches.

21. A memory cell array comprising a plurality of memory cells, each of the memory cells comprising a transistor including a self-aligned gate structure according to claim 14.

22. The memory cell array of claim 21, wherein the second gate region forms part of a wordline.

23. The memory cell array of claim 21, wherein a width of a channel of the transistor is smaller than a width of a source/drain portion of the transistor.

24. An integrated circuit including a self-aligned gate structure according to claim 14.

25. An electronic device comprising an integrated circuit including a self-aligned gate structure according to claim 14.

26. An electronic system comprising the electronic device of claim 25, wherein the electronic system is selected from the group including: a computer, a server, a router, a game console, a graphics card, a personal digital assistant, a digital camera, a cell phone, an audio system, a video system, and a processing device.

27. A memory cell array, comprising:
active areas and isolation trenches formed in a semiconductor substrate, with FinFETs disposed in the active areas, the active areas being disposed in parallel rows extending in a first direction;
bitlines extending in a second direction different from the first direction, each of the bitlines intersecting a plurality of different rows of active areas; and
wordlines extending in a third direction different from the first and the second directions, respectively, a top surface of a conductive material of the wordlines being disposed above the substrate surface.

28. The memory cell array of claim 27, further comprising capacitors disposed in a regular grid pattern.

29. The memory cell array of claim 27, wherein each of the FinFETs includes a self-aligned gate structure comprising:
a first gate region extending in semiconductor substrate portions to a lesser depth than in isolation trenches that are adjacent to the semiconductor substrate portions, the first gate region comprising a first conductive material; and
a second gate region disposed adjacent the first gate region, the second gate region extending above a surface of the semiconductor substrate, the second gate region comprising a second conductive material.

30. The memory cell array of claim 27, wherein a width of a channel of the transistor is less than a width of a source/drain portion of the transistor.

31. A method of forming a memory cell array, the method comprising:
defining isolation trenches in a semiconductor substrate;
defining vertical portions of a gate electrode extending in the isolation trenches; and
providing wordlines in contact with corresponding gate electrodes in a self-aligned manner with respect to the gate electrodes.
